(19) United States
(12) Patent Application Publication
(10) Pub. No.: US 2004/0034824 A1
(43) Pub. Date: Feb. 19, 2004

(54) System, method and computer program product for receiving and displaying store delivery system built-in-test data

(75) Inventor: Ralph J. Wasielewski, Creve Coeur, MO (US)

Correspondence Address: ALSTON & BIRD LLP, BANK OF AMERICA PLAZA, 101 SOUTH TRYON STREET, SUITE 4000, CHARLOTTE, NC, 28280-4000, US

(73) Assignee: The Boeing Company, Seattle, WA (US)

(21) Appl. No.: 10/218,791

(22) Filed: Aug. 14, 2002

(51) Int. Cl. G01R 31/28

(52) U.S. Cl. 714/733

(57) ABSTRACT

A system is provided for determining an operation failure in a store delivery system, such as a M299 Longbow Launcher. The system includes a processing element capable of communicating with the store delivery system. Thus, the processing element can initiate a built-in-test (BIT) within the store delivery system to thereby determine at least one operation failure of the store delivery system. In turn, the store delivery system is capable of generating embedded data representative of the at least one operation failure during performance of the BIT. The processing element is also capable of issuing reserved commands to the store delivery system to thereby extract the embedded data, where the store delivery system is configured to operate and perform the BIT independent of the reserved commands. The processing element can also decode the extracted data into a human-readable format that identifies the at least one operation failure.

### FIELD OF THE INVENTION

The present invention relates generally to systems and methods of operating a store launcher and, more particularly, relates to systems, methods and computer program products for receiving data from a store launcher built-in-test.

### BACKGROUND OF THE INVENTION

Modern rotorcraft, such as an Apache helicopter manufactured by The Boeing Company, are adapted to carry stores. These stores can, for example, include missiles such as anti-tank and armament piercing missiles, including the Longbow Hellfire missile manufactured by the Longbow Limited Liability Company. A missile is generally mounted to the aircraft, typically via a missile delivery system, such as the M299 Longbow Launcher also manufactured by the Longbow Limited Liability Company. In this regard, the missile delivery system interfaces with the communications system of the rotorcraft such that the rotorcraft can carry the missile to the vicinity of a target destination prior to its deployment.

Generally, the missile delivery system includes internal tactical software that allows the missile delivery system to perform a self test, including a built-in-test (BIT) of its internal circuitry. By performing the self test, the missile delivery system can better insure the missile can properly be deployed from the rotorcraft. In performing the self test, the missile delivery system generally reports if any portion or portions, such as any circuit card(s), of the missile delivery system have failed. For example, the self test can report if an interface of the missile delivery system fails to receive proper discrete signals. In this regard, the tactical software typically does not include detail regarding the failed portion(s) of the missile delivery system as a result of the self test, such as which portion of the interface designed to receive discrete signals has failed to receive proper signals.

Typically, when a portion of the missile delivery system fails the self test, the missile delivery system is removed from the rotorcraft and repaired. In repairing the missile delivery system, the failed portion(s) can be replaced and thereafter lengthy tests can be performed on the failed portion(s) to more precisely determine the problem that caused the failure. In some cases, however, external test equipment fails to detect the problem that caused the failure originally reported as a result of the self test. In such cases, test groups expend an undesirably long amount of time and resources in an attempt to identify the problem.

### SUMMARY OF THE INVENTION

In light of the foregoing background, the present invention provides a system, method and computer program product for receiving and displaying store built-in-test data. Advantageously, the system, method and computer program product of embodiments of the present invention allow operators to determine more precisely any operation failures of the store delivery system, as compared to conventional methods. In addition, the system, method and computer program product of embodiments of the present invention decode data representative of the operational failures into human-readable format that allow operators to more readily identify the operational failures.

According to one aspect of the present invention, a system is provided for determining an operation failure in a store delivery system, such as a M299 Longbow Launcher. The system includes a processing element capable of communicating with the store delivery system. For example, the processing element can be capable of communicating with the store delivery system according to a Mil-Std-1760 communications standard over a bus configured according to a Mil-Std-1553 standard. To communicate with the store delivery system, the processing element can be capable of determining a remote terminal address of the store delivery system such that the processing element issues the reserved commands based upon the determined remote terminal address.

By communicating with the store delivery system, the processing element can initiate a built-in-test (BIT) within the store delivery system, such as by issuing a BIT command, to thereby determine at least one operation failure of the store delivery system. In turn, the store delivery system is capable of generating embedded data representative of the at least one operation failure during performance of the BIT. The processing element is also capable of issuing reserved commands to the store delivery system to thereby extract the embedded data, where the store delivery system is configured to operate and perform the BIT independent of the reserved commands. For example, the processing element can issue R08/T08 commands to the store delivery system according to the Mil-Std-1553 standard to thereby extract the embedded data. The processing element can also decode the extracted data into a human-readable format that identifies the at least one operation failure. To display the decoded data in human-readable format, the system can also include a display that is responsive to the processing element.

In embodiments where the processing element communicates with the store delivery system over a bus configured according to a Mil-Std-1553 standard, the system can further comprise an interface electrically connected between the processing element and the store delivery system. In this regard, the interface can facilitate communications between the processing element and the store delivery system. Thus, in such embodiments, the interface is configured according to the Mil-Std-1553 standard.

According to other aspects of the present invention, a method of determining an operation failure in a store delivery system, and a computer program product for determining an operation failure are also provided.

### BRIEF DESCRIPTION OF THE DRAWINGS

Having thus described the invention in general terms, reference will now be made to the accompanying drawings, which are not necessarily drawn to scale, and wherein:

FIG. 1 is a control flow diagram of a store delivery system according to one embodiment of the present invention;

FIG. 2 is a block diagram of a system for determining an operation failure in a store delivery system according to one embodiment of the present invention;

FIG. 3 is a flow chart illustrating various steps in a method of determining an operation failure in a store delivery system according to one embodiment of the present invention;

FIG. 4 is an exemplar control window displayed during operation of one embodiment of the present invention;

FIG. 5 is an exemplar window displayed during operation of one embodiment of the present invention, where the window presents the words of a R08 message transmitted according to one embodiment of the present invention;

FIG. 6 is an exemplar window displayed during operation of one embodiment of the present invention, where the window presents the words of a T08 message transmitted according to one embodiment of the present invention; and

FIG. 7 is an exemplar window displayed during operation of one embodiment of the present invention, where the window illustrates embedded data generated during a BIT decoded into a human-readable format.

### DETAILED DESCRIPTION OF THE INVENTION

The present invention now will be described more fully hereinafter with reference to the accompanying drawings, in which preferred embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. Like numbers refer to like elements throughout.

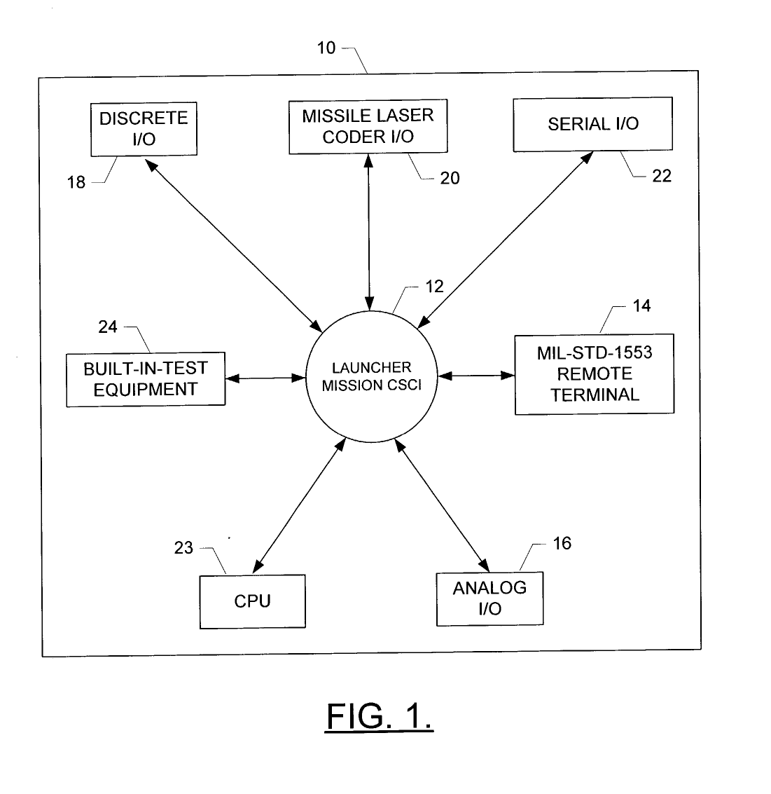

Referring to FIG. 1, a control flow diagram is shown for a store delivery system 10, such as the M299 Longbow Launcher manufactured by the Longbow Limited Liability Company. The store delivery system generally provides an interface between at least one store, such as a missile, and equipment carrying out the launch of the missile, such as a rotorcraft. As known to those skilled in the art, the store delivery system typically includes a Computer Software Configuration Item (CSCI) module 12 that generally communicates with a bus controller of the system to respond to bus controller commands and report store delivery system and missile status. The CSCI module also provides control and launch of the missile, such as semi-active laser (SAL), Hellfire optimized missile system (HOMS), and radio frequency (RF) missiles. For example, the CSCI module can provide “make ready” and “mode switching” to the store to thereby control operation of the store, as such is known to those skilled in the art. In addition, the CSCI module also communicates with or receives commands from test equipment that operates as the bus controller to perform reprogramming operations of the store delivery system.

As also shown in FIG. 1, the CSCI module 12 interfaces with a number of different devices within the store delivery system 10 to thereby carry out the functions of the CSCI module. The CSCI module interfaces with a remote terminal 14, such as a remote terminal capable of communicating via a bus configured according to the Mil-Std-1553 standard, to carry out all command and reporting sequences required for operation of the missiles. In this regard, the remote terminal is the primary data interface to and from the bus controller. The CSCI module also interfaces with an analog input/output (I/O) 16, which represents an interface with the store delivery system electronics assembly, or launcher electronics assembly (LEA) hardware, which can sense the state of discrete inputs and command the state of discrete outputs within the store delivery system, such as from discrete I/O 18. As such, the CSCI module interfaces with the analog I/O to perform the operational mission of the CSCI module. The interface between the CSCI module and the analog I/O is also used by the CSCI module to determine whether the store delivery system is being commanded to perform reprogramming, as such is known.

The CSCI module 12 also interfaces with a missile laser coder I/O 20, which represents the interface with the LEA hardware that allows a laser missile (e.g., SAL and HOMS) pulse repetition frequency (PRF) and alternate coding sequences to take place. In this regard, communications with the laser missile seeker typically occur via a serial interface, or serial I/O 22. The interface with laser coder I/O is used by the CSCI module to perform its operational mission. More particularly, the serial I/O interface represents the interface with the LEA hardware that allows the CSCI module to provide serial communications to the RF missile. In this regard, this interface will also be used by the CSCI module to perform its operational mission. The CSCI module also interfaces with a central processing unit (CPU) 23, which allows the tactical software of the store delivery system 10 to perform the CSCI functions.

The interface between the CSCI module 12 and the built-in-test equipment (BITE) 24, in conjunction with the other interfaces, allows the CSCI module to perform a built-in-test (BIT) on the hardware of the store delivery system 10 in accordance with a predefined internal test routine maintained in memory within the store delivery system. The BITE can perform many tests on the hardware to insure proper operation of the store delivery system. For example, the BITE can perform a test of the analog I/O 16 by determining if any failures exist in the input or output of the analog I/O. Similarly, the BITE can perform a test of the discrete I/O 18 to determine if any failures exist in the input or output of the discrete I/O. The BITE generally includes internal tactical software, typically written in the Ada language, that allows the missile delivery system to perform the built-in-test (BIT) of its internal circuitry. In performing the BIT, the BITE generally reports if any portion or portions, such as any circuit card(s), of the missile delivery system have failed. In this regard, the tactical software typically does not include detail regarding the failed portion(s) of the missile delivery system as a result of the self test.

As known to those skilled in the art, a store delivery system, such as the M299 Longbow Launcher, was developed with a software test plan that allows for embedded capabilities not directly associated with the store delivery system's primary function in the tactical software. Such embedded capabilities allow operators, such as software developers, to test the required functions and sub-functions of the store delivery system 10 by utilizing the remote terminal interface 14 to the store delivery system. In this regard, a dedicated number of communications messages, referred to herein as reserve messages or commands, which are not required for operation of the store delivery system, are included within the tactical software. For development purposes, then, such reserved messages allow developers to access internal parameters of the sub-functions of the store delivery system. In 1553 communications for the M299 Longbow Launcher, for example, sub-address 8 in the tactical software is reserved for such capability. Thus, internal parameters of the sub-functions of the M299 Longbow Launcher may be accessed by transmitting to and receiving responses from sub-address 8 in the tactical software. As the reserved messages or commands correspond to transmitting and receiving information to and receiving responses from the store delivery system via the remote terminal interface, the dedicated messages can be referred to as R08/T08 messages (R representing receive messages, and T representing transmit messages).

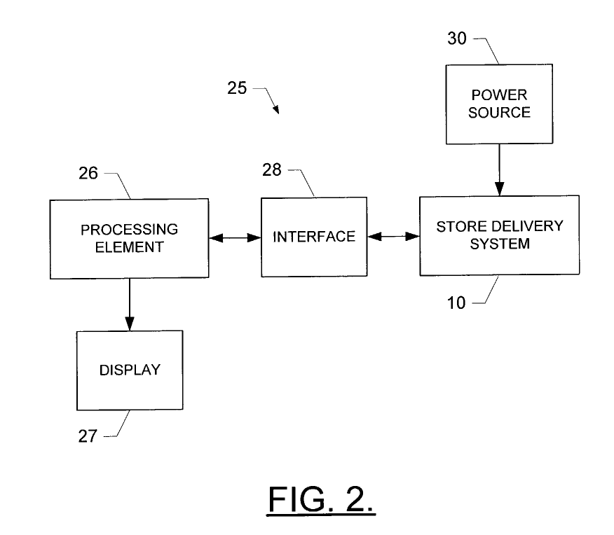

Therefore, according to the present invention, a system, method and computer program product are provided for performing a BIT, and thereafter utilize R08/T08 messages to automatically extract embedded data from within the internal BIT function and decode the data into human-readable text that can be displayed and/or stored by an operator. In this regard, embedded data generally comprises data generated and stored by the store delivery system in performing subroutines of the BIT. In this regard, while the embedded data is generated and stored during the BIT, the store delivery system typically only uses such data to determine whether a failure of the BIT has occurred and, as such, does not report or otherwise output such data. Referring now to FIG. 2, the system 25 includes a processing element 26 adapted to communicate with a store delivery system 10, such as the M299 Longbow Launcher. The processing element can comprise any of a number of different devices, such as a personal computer or other high level processor. In this regard, the processing element can communicate with the store delivery system according to any of a number of known methods but, according to one embodiment, the processing element communicates with the store delivery system according to the Mil-Std-1760 communications standard over a bus configured according to the Mil-Std-1553 standard. In addition, the processing element can drive a display 27, such as a viewing screen, monitor or the like, which is responsive to the processing element. As described more fully below, the display can advantageously present BIT data from the store delivery system in a human-readable format.

To facilitate communications between the processing element 26 and the store delivery system 10, the system 25 can also include an interface 28 electrically connected between the processing element 26 and the store delivery system 10. For example, the interface can comprise a Personal Computer Memory Card International Association (PCMCIA) card, configured to communicate over a bus configured to the Mil-Std-1553 standard, such as are manufactured by Data Device Corporation of Bohemia, N.Y. Also, to operate the store delivery system to perform the BIT, the store delivery system is provided with power from a power source 30, which provides the necessary operating power. The power source can comprise any of a number of different power sources capable of providing required operating power to the store delivery system. For example, when the store delivery system comprises a M299 Longbow Launcher, the power source is capable of providing power to the M299 Longbow Launcher comprising 28 Volt DC power, as well as 115 Volt AC power at 400 Hz, as such is known to those skilled in the art.

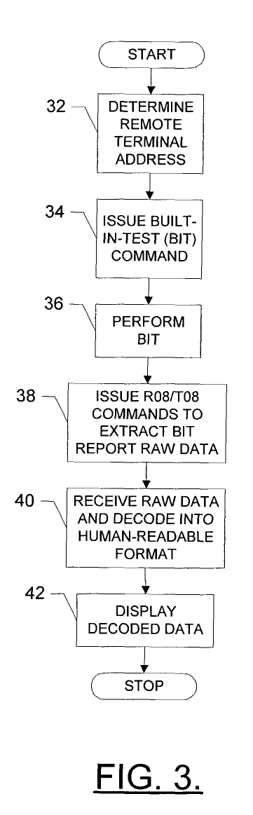

Reference is now drawn to FIG. 3, which illustrates various steps in a method of determining operation failures in the store delivery system 10 according to one embodiment of the present invention. The method will be described in terms of a Discrete-In BIT, as such is known to those skilled in the art. It should be understood, however, that the method can be performed with any of a number of different BITs without departing from the spirit and scope of the present invention. Upon power up of the store delivery system, the method of determining operation failures typically begins with the processing element 26 determining a remote terminal address associated with the store delivery system, as shown in block 32. The processing element can determine the remote terminal address according to any number of methods. For example, the processing element can determine the remote terminal address by acquiring a known remote terminal address for the store delivery system, such as by an operator configuring the processing element with a known remote terminal address.

In embodiments where the processing element does not acquire a known remote terminal address, and where the processing element 26 and store delivery system 10 communicate according to the Mil-Std-1760 communications standard, the processing element can determine the remote terminal address by iteratively requesting a status message from the store delivery system for each available remote terminal address until the processing element receives a response from the store delivery system. The address at which the processing element sent the immediately preceding status request, then, becomes the remote terminal address for future communications between the processing element and the store delivery system. It will be appreciated that as the processing element sets the remote terminal address to the first address that returns a response from the status request, the store delivery device is preferably the only addressed device electrically connected to the processing element via the interface.

As is known to those skilled in the art, according to the Mil-Std-1760 communications standard, only 32 addresses are available on the communications bus (e.g., Mil-Std-1553 communications bus). And when a bus master (e.g., processing element 26) desires to communicate with (or address) a particular device (e.g., store delivery system 10) on the data bus, the bus master will encode the address of the device in its data packet protocol. Typically, every device on the data bus, then, analyzes the address bits and only the device that has matching bits to its specific address will accept the data packet. In this regard, each device must have a unique address. Thus, according to the Mil-Std-1760 specification, prior to the processing element determining the remote terminal address, store delivery system can acquire a remote terminal address by using jumpers to set the address, such as via five connector pins (also including a parity connection). Alternatively, the processing element can be configured with a remote terminal address, and thereafter the store delivery system can be configured with the same remote terminal address, such as by setting the jumpers.

Once the processing element 26 has determined the remote terminal address of the store delivery system 10, the processing element can communicate with the store delivery system by addressing the store delivery system according to the remote terminal address. In this regard, the processing element can initiate a BIT within the store delivery system, such as by issuing a BIT command (perform Discrete-In BIT) to the store delivery system via the interface 28, as shown in block 34. The BIT command is transmitted from the processing element through the interface to the store delivery system. In turn, the store delivery system receives the BIT command and, in response, performs the commanded BIT in accordance with a predefined internal test routine maintained in memory within the store delivery system. As will be appreciated by those skilled in the art, as the store delivery system performs the BIT, the store delivery system generates embedded data representative of specific operation failures during subroutines of the BIT. And even though the store delivery system generates more detailed data regarding specific operation failures, the store delivery system typically only returns a high level failure indication at the conclusion of the BIT.

Thus, as the store delivery system 10 performs the BIT or at the conclusion of the BIT, the processing element 26 transmits one or more R08 messages to automatically extract the embedded data representative of specific operation failures from within the internal BIT function, as shown in block 38. For example, as used with the tactical software of the M299, the processing element could transmit an “IBIT_Report_Cmd” command to the store delivery system, as such is known. In response to the R08 messages, the store delivery system prepares the embedded data for transmission to the processing element. For example, during operation of the BIT, the store delivery system can store the embedded data as bits in internal memory locations, typically in hexadecimal format, to designate operation failures.

In response to the R08 commands, the store delivery system 10 accesses the memory locations including the embedded data and repacks the embedded data in a message capable of being transmitted back to the processing element 26, such as a 1553 message. The processing element can then transmit one or more T08 messages to the store delivery system that cause the store delivery system to transmit the message including the embedded data back to the processing element. Upon receipt of the message including the embedded data, the processing element 26 decodes the data into a human-readable format to allow an operator to more readily identify the operation failures represented by the data, as shown in block 40. The processing element can decode the data into any one of a number of different formats but, according to one embodiment, the processing element decodes the data into a text format that identifies the operating failures represented by the embedded data, an example of which is shown in FIG. 7 and described below.

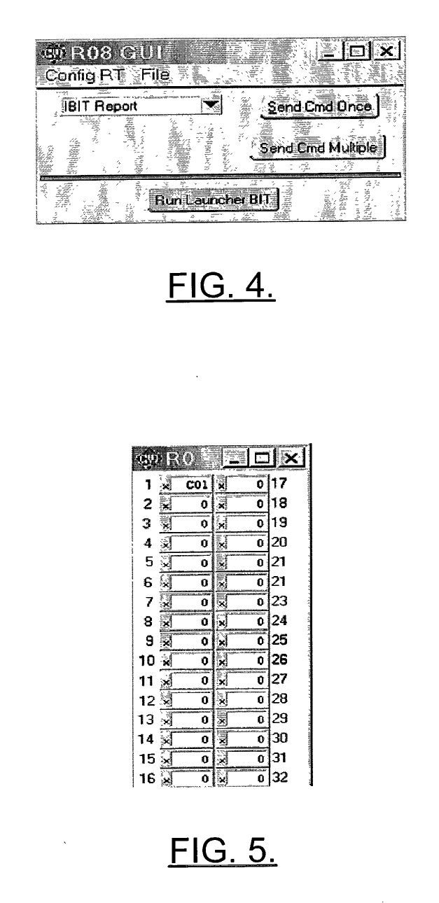

As stated above, the processing element 26 can drive a display 27. In this regard, the display can facilitate an operator controlling the processing element to perform the various steps of the method described above, as well as present the operator with the decoded data from the processing element. Thus, FIGS. 4-7 represent exemplar windows that the processing element could drive the display to present during operation of the present invention. For example, FIG. 4 illustrates a control window whereby the operator can choose to command the processing element to initiate the BIT within the store delivery system 10. Additionally, the control window can allow the operator to choose to have the processing element transmit the R08/T08 messages to the store delivery system to extract the embedded data and thereafter decode the embedded data into human-readable format and present the human-readable information.

As shown in FIG. 5, the processing element 26 can drive the display 27 to present the R08 message transmitted by the processing element to the store delivery system 10. As shown, for example, the display can present the message as a series of 32 separately identified words. For example, the message transmitted can consist of one word that includes the 1553 message “C01,” which in the Ada software language for the M299 tactical software, is the hexadecimal form of the R08 message “IBIT_Report Cmd.”

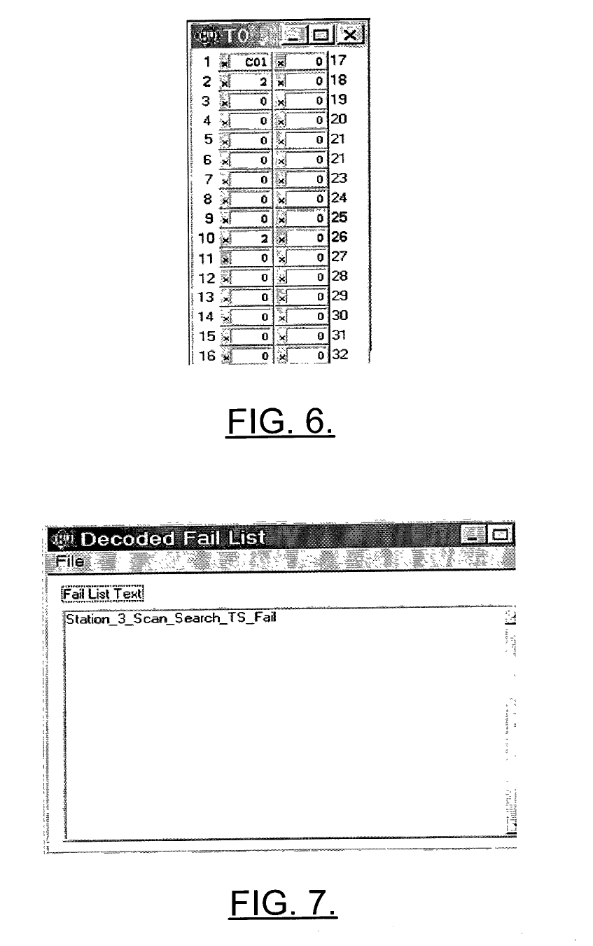

As shown in FIG. 6, similar to presenting the R08 message transmitted to the store delivery system 10, the processing element 26 can drive the display 27 to present the T08 message received by the processing element from the store delivery system. Also, similar to presenting the R08 message, the message received from the store delivery system in response to the T08 message from the processing element can also be presented as a series of 32 separately identified words. For example, then, the response message can include an echo of the R08 message (designated by repeating the word “C01” of the R08 message), as well as a command complete handshake (identified by the second word of the message, “2”). The embedded data from the store delivery system identifying operation failures, can be represented by words 3-32, where a “0” indicates non-failure. As shown, for example, the store delivery system can return an operation failure by including a word in the return message identifying the operation failure by word number. Thus, by including the word “2” as the 10th word of the response message, the processing element can decode the data according to placement of the word in the response message.

Upon decoding the data, then, the processing element 26 can drive the display 27 to present the embedded data in human-readable format, such as a test format, as shown in FIG. 7, for example. As illustrated in FIG. 7, the data word “2” in the 10th word of the response message from the store delivery system 10 can be decoded by the processing element to identify a failure of the Station 3 Scan Search TS in a Discrete-In BIT, which could identify a failure of the laser missile Stare Command interface, BIT monitor feedback circuit, for the missile located on Station 3 of the store delivery system, as such is known. In this regard, store delivery systems such as the M299 Longbow Launcher include four identical missile interfaces and, as such, a failure at Station 3 identifies a failure in the circuitry for the third missile interface.

Thus, the present invention provides a system, method and computer program product that allow operators to receive more detailed BIT information regarding the store delivery system status after the store delivery system tactical software has performed the BIT. Thus, by more readily delivering detailed BIT information, troubleshooting and repair of failed components of the store delivery system can be expedited. In this regard, by providing information as to problems causing BIT failures, lengthy tests previously performed on the failed portion(s) to more precisely determine the problem that caused the failure can be avoided.

The methods of the present invention is generally implemented by one or more computer processing elements, such as microprocessors or the like. For example, all or a portion of the methods can be performed by the processing element 26. The computer processing elements typically operate under the control of a computer program product. The computer program product includes a computer-readable storage medium, such as a non-volatile storage medium, and computer-readable program code portions, such as a series of computer instructions, embodied in the computer-readable storage medium. Typically, the computer program product is stored by the computer processing element or a related memory device.

In this regard, FIGS. 1, 2 and 3 are block diagrams and control flow illustrations of methods, systems and program products according to the invention. It will be understood that each block or step of the block diagram, flowchart and control flow illustrations, and combinations of blocks in the block diagram, flowchart and control flow illustrations, can be implemented by computer program instructions. These computer program instructions may be loaded onto a computer or other programmable apparatus to produce a machine, such that the instructions which execute on the computer or other programmable apparatus create means for implementing the functions specified in the block diagram, flowchart or control flow block(s) or step(s). These computer program instructions may also be stored in a computer-readable memory that can direct a computer or other programmable apparatus to function in a particular manner, such that the instructions stored in the computer-readable memory produce an article of manufacture including instruction means which implement the function specified in the block diagram, flowchart or control flow block(s) or step(s). The computer program instructions may also be loaded onto a computer or other programmable apparatus to cause a series of operational steps to be performed on the computer or other programmable apparatus to produce a computer implemented process such that the instructions which execute on the computer or other programmable apparatus provide steps for implementing the functions specified in the block diagram, flowchart or control flow block(s) or step(s).

Accordingly, blocks or steps of the block diagram or control flow illustrations support combinations of means for performing the specified functions, combinations of steps for performing the specified functions and program instruction means for performing the specified functions. It will also be understood that each block or step of the block diagram, flowchart or control flow illustrations, and combinations of blocks or steps in the block diagram, flowchart or control flow illustrations, can be implemented by special purpose hardware-based computer systems which perform the specified functions or steps, or combinations of special purpose hardware and computer instructions.

Many modifications and other embodiments of the invention will come to mind to one skilled in the art to which this invention pertains having the benefit of the teachings presented in the foregoing descriptions and the associated drawings. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation.

What is claimed is:

1. A method of determining an operation failure in a store delivery system comprising:
performing a built-in-test (BIT) within the store delivery system to thereby determine at least one operation failure of the store delivery system, wherein performing the BIT comprises generating embedded data representative of the at least one operation failure;
issuing reserved commands to the store delivery system to thereby extract the embedded data, wherein the store delivery system is configured to operate and perform the BIT independent of the reserved commands; and
decoding the extracted data into a human-readable format that identifies the at least one operation failure.

2. A method according to claim 1 further comprising displaying the decoded data in human-readable format.

3. A method according to claim 1 further comprising determining a remote terminal address of the store delivery system, wherein issuing reserved commands is based upon the determined remote terminal address.

4. A method according to claim 1 further comprising issuing a BIT command to the store delivery system before performing the BIT.

5. A method according to claim 1, wherein the store delivery system comprises an M299 Longbow Launcher, and wherein issuing reserved commands comprises issuing R08/T08 commands according to a Mil-Std-1553 standard.

6. A system for determining an operation failure in a store delivery system comprising:
a processing element capable of communicating with the store delivery system, wherein said processing element is capable of initiating a built-in-test (BIT) within the store delivery system to thereby determine at least one operation failure of the store delivery system, wherein the store delivery system is capable of generating embedded data representative of the at least one operation failure during performance of the BIT, wherein said processing element is also capable of issuing reserved commands to the store delivery system to thereby extract the embedded data, wherein the store delivery system is configured to operate and perform the BIT independent of the reserved commands, and wherein said processing element is capable of decoding the extracted data into a human-readable format that identifies the at least one operation failure.

7. A system according to claim 6 further comprising a display, responsive to said processing element, for displaying the decoded data in human-readable format.

8. A system according to claim 6, wherein said processing element is capable of determining a remote terminal address of the store delivery system such that said processing element issues the reserved commands based upon the determined remote terminal address.

9. A system according to claim 6, wherein said processing element is capable of issuing a BIT command to the store delivery system to thereby initiate the BIT within the store delivery system.

10. A system according to claim 6, wherein the store delivery system comprises an M299 Longbow Launcher, and wherein said processing element is capable of issuing R08/T08 commands according to a Mil-Std-1553 standard.

11. A system according to claim 6, wherein said processing element is capable of communicating with the store delivery system according to a Mil-Std-1760 communications standard over a bus configured according to a Mil-Std-1553 standard.

12. A system according to claim 11 further comprising an interface electrically connected between said processing element and the store delivery system, wherein said interface is capable of facilitating communications between said processing element and the store delivery system, and wherein said interface is configured according to the Mil-Std-1553 standard.

13. A computer program product for determining an operation failure in a store delivery system, said computer program product comprising a computer-readable storage medium having computer-readable program code portions stored therein, the computer-readable program portions comprising:
a first executable portion for initiating a built-in-test (BIT) within the store delivery system to thereby determine at least one operation failure of the store delivery system, wherein the store delivery system generates embedded data representative of the at least one operation failure during performance of the BIT;
a second executable portion for issuing reserved commands to the store delivery system to thereby extract the embedded data, wherein the store delivery system is configured to operate and perform the BIT independent of the reserved commands; and
a third executable portion for decoding the extracted data into a human-readable format that identifies the at least one operation failure

14. A computer program product according to claim 13 further comprising a fourth executable portion for displaying the decoded data in human-readable format.

15. A computer program product according to claim 13 further comprising a fourth executable portion for determining a remote terminal address of the store delivery system, wherein said second executable portion issues reserved commands based upon the determined remote terminal address.

16. A computer program product according to claim 13, wherein said first executable portion initiates the BIT by issuing a BIT command to the store delivery system.

17. A computer program product according to claim 13, wherein the store delivery system comprises an M299 Longbow Launcher, and wherein said second executable portion issues reserved commands comprising R08/T08 commands according to a Mil-Std-1553 standard.
